(19) United States
(12) Patent Application Publication
(10) Pub. No.: US 2023/0321871 A1
(43) Pub. Date: Oct. 12, 2023

(54) WAFER MANUFACTURING METHOD

(71) Applicant: DISCO CORPORATION, Tokyo (JP)

(72) Inventors: Kazuya HIRATA, Tokyo (JP); Satoshi GENDA, Tokyo (JP); Asahi NOMOTO, Tokyo (JP)

(21) Appl. No.: 18/297,102

(22) Filed: Apr. 7, 2023

(30) Foreign Application Priority Data
Apr. 11, 2022 (JP) 2022-065078

(51) Int. Cl. B28D 1/22; B23K 26/00; B23K 26/53

(52) U.S. Cl. CPC B28D 1/226; B28D 1/221; B23K 26/0006; B23K 26/53; B23K 2103/52

(57) ABSTRACT

A wafer manufacturing method includes a peeling start point forming step of applying, to an ingot, a laser beam of such a wavelength as to be transmitted through the ingot, with a focal point of the laser beam positioned at a depth corresponding to the thickness of a wafer to be manufactured, from an end face of the ingot, to form a peeling start point, and a peeling step of peeling off, from the peeling start point, the wafer to be manufactured from the ingot. In the peeling step, degassed water is supplied to the end face of the ingot to generate a degassed water layer, and an ultrasonic wave is applied to break the peeling start point.

### BACKGROUND OF THE INVENTION

### Field of the Invention

The present invention relates to a wafer manufacturing method for manufacturing a wafer from an ingot.

### Description of the Related Art

Devices such as integrated circuits (ICs), large-scale integration (LSI) circuits, and light emitting diodes (LEDs) are formed by laminating a functional layer on a front surface of a wafer formed of such a material as silicon (Si) and sapphire (Al₂O₃) and partitioning the devices by a plurality of projected dicing lines (streets) intersecting the functional layer. In addition, power devices, LEDs, and the like are formed by laminating a functional layer on a front surface of a wafer formed of silicon carbide (SiC) as a material and partitioning the devices by a plurality of streets intersecting the functional layer.

The wafer formed with the devices is subjected to processing of the streets by a cutting apparatus or a laser processing apparatus to be thereby divided into individual device chips, and the divided device chips are used for electric apparatuses such as mobile phones and personal computers.

The wafer to be formed with the devices is typically manufactured by slicing a cylindrical ingot by a wire saw. The front surface and a back surface of the wafer thus manufactured are finished to a mirror surface by polishing (see, for example, Japanese Patent Laid-open No. 2000-94221).

However, when the ingot is cut by the wire saw and the front surface and the back surface of the cut wafer are polished, most part (70% to 80%) of the ingot would be discarded, which is uneconomical. Particularly, in the case of an SiC ingot, SiC has a high hardness, is difficult to cut by the wire saw, and requires a considerable time to be cut, so that productivity is poor. In addition, the ingot is high in unit cost. Hence, there is a problem in efficiently manufacturing the wafer.

In view of the above-mentioned problems, the present applicant has proposed a technology in which a laser beam of such a wavelength as to be transmitted through SiC is applied to an SiC ingot with a focal point of the laser beam positioned inside the SiC ingot, to form a peeling start point on a projected cutting plane, and the wafer is peeled off from the ingot along the projected cutting plane formed with the peeling start point (see, for example, Japanese Patent Laid-open No. 2016-111143).

In addition, the present applicant has also proposed a technology of applying an ultrasonic wave to an ingot through a layer of water for the purpose of facilitating peeling of the wafer to be manufactured from the ingot (see, for example, Japanese Patent Laid-open No. 2016-146446).

### SUMMARY OF THE INVENTION

However, although application of an ultrasonic wave to the ingot formed with the peeling start point enhances peeling properties, a certain time is taken until the wafer is peeled off from the ingot, so that it is desired to shorten the time from the start of ultrasonic wave application to the completion of peeling of the wafer.

Such a problem would occur also in the case of peeling off a wafer from an ingot of Si, Al₂O₃, or the like by applying a laser beam of such a wavelength as to be transmitted through the ingot of Si, Al₂O₃, or the like to the ingot, with a focal point of the laser beam positioned inside the ingot, to form a peeling start point.

Accordingly, it is an object of the present invention to provide a wafer manufacturing method by which a wafer can efficiently be peeled off.

In accordance with an aspect of the present invention, there is provided a wafer manufacturing method for manufacturing a wafer from an ingot. The method includes a peeling start point forming step of applying, to the ingot, a laser beam of such a wavelength as to be transmitted through the ingot, with a focal point of the laser beam positioned at a depth corresponding to a thickness of the wafer to be manufactured, from an end face of the ingot, to form a modified layer, thereby forming a peeling start point, and a peeling step of peeling off, from the peeling start point, the wafer to be manufactured from the ingot. In the peeling step, degassed water is supplied to the end face of the ingot to generate a degassed water layer, and an ultrasonic wave is applied to break the peeling start point.

Preferably, in the peeling step, the ultrasonic wave is applied to water reserved in a decompression tank, to decompress an inside of the decompression tank, thereby generating the degassed water. Preferably, in the peeling step, degassed water having an oxygen content of not more than 2.0 mg/liter is generated.

Preferably, the ingot may be an SiC ingot. The SiC ingot has a first surface, a second surface on a side opposite to the first surface, a c-axis extending from the first surface to the second surface, and a c-plane orthogonal to the c-axis. The c-axis is inclined relative to a perpendicular to the first surface. The off-angle is formed by the c-plane and the first surface. The peeling start point forming step includes a modified layer forming step of relatively moving the focal point of the laser beam and the SiC ingot in a direction orthogonal to a direction in which the off-angle is formed, to form a rectilinear modified layer, and an indexing step of relatively moving the focal point of the laser beam and the SiC ingot in the direction in which the off-angle is formed, to thereby perform index feeding by a predetermined amount.

According to the wafer manufacturing method of the present invention, in the peeling step, the degassed water is supplied to the end face of the ingot to generate the layer of the degassed water, and the ultrasonic wave is applied to break the peeling start point, so that the wafer can efficiently be peeled off.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of an ingot;

FIG. 1B is a plan view of the ingot depicted in FIG. 1A;

FIG. 1C is a front view of the ingot depicted in FIG. 1A;

FIG. 2A is a perspective view depicting a peeling start point forming step;

FIG. 2B is a front view depicting the peeling start point forming step;

FIG. 2C is a sectional view of the ingot formed with a peeling start point;

FIG. 3 is a sectional view depicting a state in which degassed water is generated;

FIG. 4 is a sectional view depicting an example of a state in which a wafer is peeled off from the ingot;

and

FIG. 5 is a front view depicting another example of the state in which the wafer is peeled off from the ingot.

### DETAILED DESCRIPTION OF THE PREFERRED EMBODIMENT

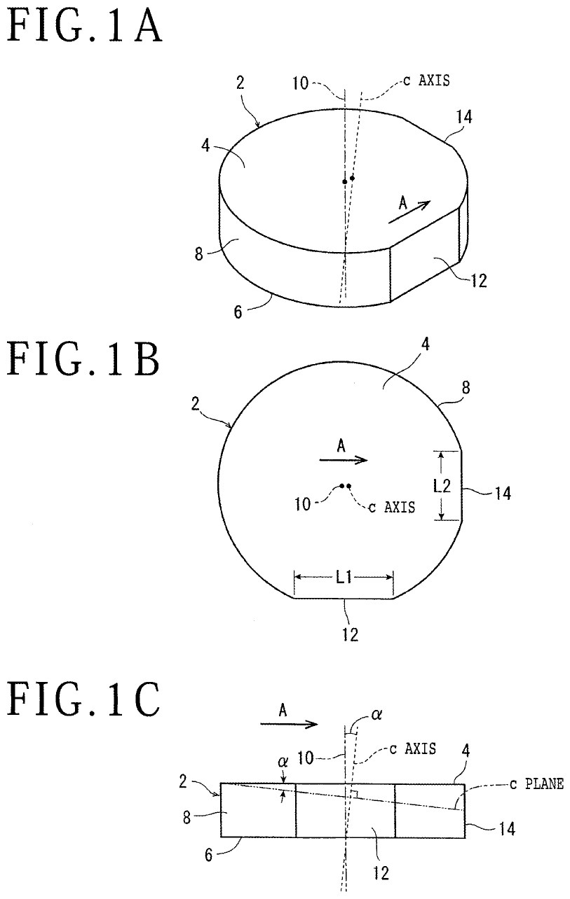

A wafer manufacturing method according to an embodiment of the present invention will be described in detail below with reference to the drawings. FIGS. 1A to 1C depict a cylindrical ingot 2 which is subjected to processing by the wafer manufacturing method of the present invention. The ingot 2 illustrated is formed of single crystal SiC.

The ingot 2 has a circular first surface 4, a circular second surface 6 located on the side opposite to the first surface 4, a circumferential surface 8 located between the first surface 4 and the second surface 6, a c-axis extending from the first surface 4 to the second surface 6, and a c-plane (see FIG. 1C) orthogonal to the c-axis. At least the first surface 4 is flattened by grinding or polishing to such an extent as not to hamper the incidence of a laser beam thereon.

In the ingot 2, the c-axis is inclined relative to a perpendicular 10 to the first surface 4, and an off-angle α (for example, α=1, 3, or 6 degrees) is formed by the c-plane and the first surface 4. A direction in which the off-angle α is formed is indicated by an arrow A in FIGS. 1A to 1C.

The circumferential surface 8 of the ingot 2 is formed with a first orientation flat 12 and a second orientation flat 14 which are rectangular and indicate crystal orientation. The first orientation flat 12 is parallel to the direction A in which the off-angle α is formed, whereas the second orientation flat 14 is orthogonal to the direction A in which the off-angle α is formed. As depicted in FIG. 1B, when viewed from above, a length L2 of the second orientation flat 14 is shorter than a length L1 of the first orientation flat 12 (L2<L1).

Note that the ingot subjected to processing by the wafer manufacturing method of the present invention is not limited to the above-described ingot 2, and may be an SiC ingot in which the c-axis is not inclined to the perpendicular to the first surface and the off-angle α by the c-axis and the first surface is 0 degrees (in other words, the perpendicular to the first surface and the c-axis coincide with each other), or an ingot formed of a material other than SiC, such as Si, Al₂O₃, or gallium nitride (GaN).

(Peeling Start Point Forming Step)

In the present embodiment, carried out first is a peeling start point forming step in which a laser beam of such a wavelength as to be transmitted through the ingot 2 is applied to the ingot 2 with a focal point of the laser beam positioned at a depth corresponding to the thickness of the wafer to be manufactured, from an end face of the ingot 2, to form a modified layer and thereby form a peeling start point.

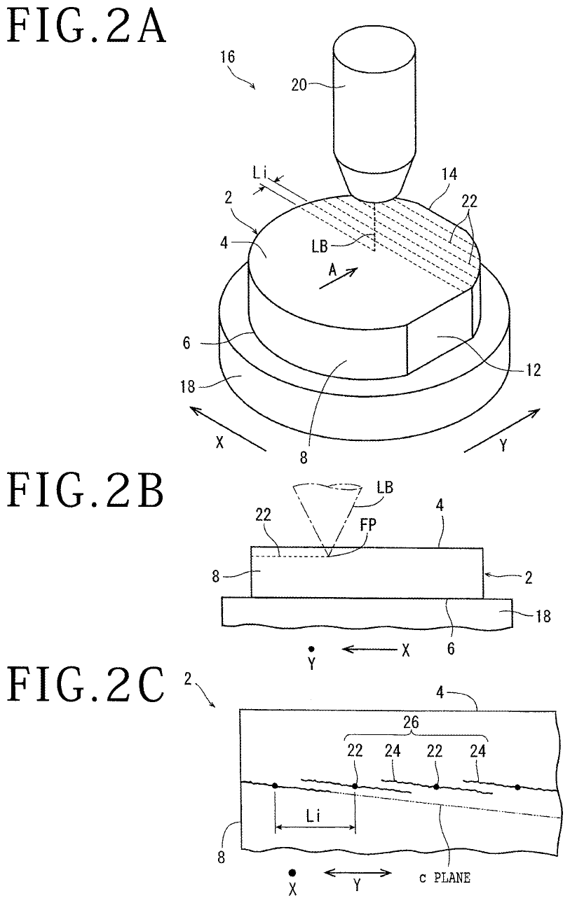

The peeling start point forming step can be performed, for example, by use of a laser processing apparatus 16 depicted in FIG. 2A. The laser processing apparatus 16 includes a chuck table 18 that holds the ingot 2 under suction, a laser oscillator (not illustrated) that emits a pulsed laser beam LB of such a wavelength as to be transmitted through the ingot 2, and a light concentrating unit 20 that concentrates the pulsed laser beam LB emitted by the laser oscillator and applies the pulsed laser beam LB to the ingot 2 held under suction by the chuck table 18.

The chuck table 18 is configured to be rotatable around an axis extending in the vertical direction and movable in an X-axis direction indicated by an arrow X in FIG. 2A and a Y-axis direction (the direction indicated by an arrow Y in FIG. 2A) orthogonal to the X-axis direction. Note that an XY plane defined by the X-axis direction and the Y-axis direction is substantially horizontal.

Continuing description with reference to FIGS. 2A to 2C, in the peeling start point forming step, first, the ingot 2 is held under suction by an upper surface of the chuck table 18, with the first surface 4 directed upward. Next, the ingot 2 is imaged from above by an imaging unit (not illustrated) of the laser processing apparatus 16, and, on the basis of an image of the ingot 2 picked up by the imaging unit, the orientation of the ingot 2 is adjusted to a predetermined direction, and the positional relation between the ingot 2 and the light concentrating unit 20 is adjusted.

At the time of adjusting the orientation of the ingot 2 to the predetermined direction, the second orientation flat 14 is matched to the X-axis direction, as depicted in FIG. 2A. As a result, a direction orthogonal to the direction A in which the off-angle α is formed is matched to the X-axis direction, and the direction A in which the off-angle α is formed is matched to the Y-axis direction.

Subsequently, a focal point FP (see FIG. 2B) of the laser beam LB is positioned at a depth corresponding to the thickness of the wafer to be manufactured, from the first surface 4 of the ingot 2. Next, while the focal point FP and the ingot 2 are relatively moved in the X-axis direction (the direction orthogonal to the direction A in which the off-angle α is formed), a laser beam LB of such a wavelength as to be transmitted through the ingot 2 is applied from the light concentrating unit 20 to the ingot 2. As a result, as depicted in FIG. 2C, a rectilinear modified layer 22 in which SiC is separated into Si and carbon (C) can be formed along the X-axis direction. In addition, cracks 24 extending from the modified layer 22 along the c-plane are also formed (modified layer forming step).

Subsequently, the focal point FP and the ingot 2 are subjected to relative index feeding (indexing step) in the Y-axis direction (the direction A in which the off-angle α is formed). An indexing amount Li is a length not exceeding the width of the crack 24 such that the cracks 24 adjacent to each other in the Y-axis direction overlap with each other as viewed in the vertical direction. Then, the modified layer forming step and the indexing step are alternately repeated, whereby a peeling start point 26 having pluralities of modified layers 22 and cracks 24 are formed at a depth (projected cutting plane) corresponding to the thickness of the wafer to be manufactured.

Such a peeling start point forming step can be carried out, for example, under the following processing conditions.

Wavelength of pulsed laser beam: 1,064 nm

Repetition frequency: 80 kHz

Average output: 3.2 W

Pulse width: 4 ns

Diameter of focal point: 10 μm

Numerical aperture (NA): 0.45

Indexing amount: 400 μm

Thickness of wafer to be manufactured: 700 μm

(Peeling Step)

After the peeling start point forming step is conducted, a peeling step of peeling off, from the peeling start point 26, the wafer to be manufactured from the ingot 2 is carried out.

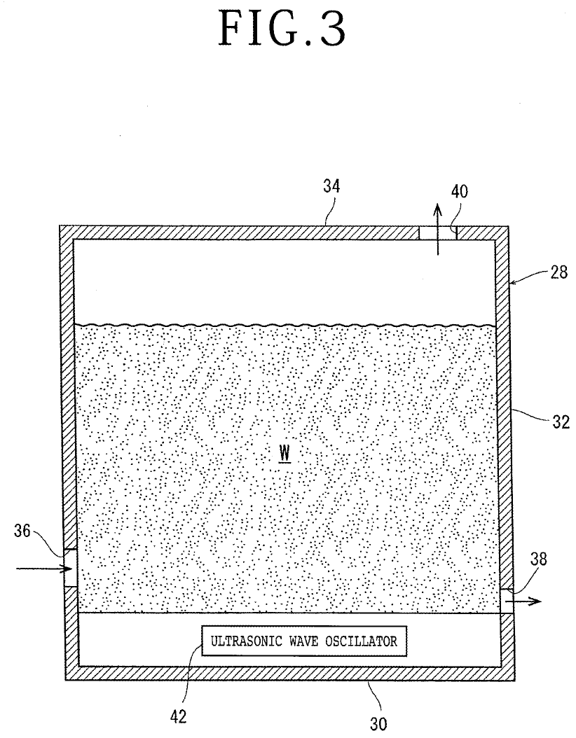

In the peeling step, first, an ultrasonic wave is applied to water reserved in a decompression tank, to decompress the inside of the decompression tank, thereby generating degassed water. At the time of generating the degassed water, for example, a decompression tank 28 depicted in FIG. 3 can be used.

The decompression tank 28 includes a bottom plate 30, a side wall 32 extending upward from a peripheral edge of the bottom plate 30, and a top plate 34 provided at an upper end of the side wall 32. The side wall 32 is formed with a supply port 36 for supplying, into the decompression tank 28, water W that has not yet been subjected to degassing and a discharge port 38 for discharging the degassed water from the decompression tank 28. The top plate 34 is provided with a suction hole 40, which is connected to a vacuum pump (not illustrated). In addition, an ultrasonic wave oscillator 42 is disposed in the inside of the decompression tank 28.

At the time of generating the degassed water, first, water W that has not yet been subjected to degassing is supplied through the supply port 36 into the decompression tank 28. Next, the ultrasonic wave oscillator 42 is operated to apply an ultrasonic wave (for example, on the order of 0.1 to 1.0 MHz) to the water W. In addition, the vacuum pump is operated to decompress the inside of the decompression tank 28. As a result, as depicted in FIG. 3, gas having been dissolved in the water W appears as bubbles, and the gas can be removed from the water W. In this way, by applying the ultrasonic wave to the water W reserved in the decompression tank 28 and decompressing the inside of the decompression tank 28, the degassed water can be generated.

It is preferable that the air pressure inside the decompression tank 28 at the time of generating the degassed water be as low as possible. This is because the degassing is accelerated as the decompression proceeds more. The relation between the air pressure inside the decompression tank 28 and the oxygen content of the degassed water will be indicated below.

| | Lower limit of oxygen |
|---|---|
| Air pressure inside | content of degassed |
| decompression tank (atm) | water (mg/liter) |
| 1.0 | 8.1 |
| 0.7 | 6.55 |
| 0.65 | 5.8 |
| 0.6 | 5.48 |
| 0.5 | 4.97 |
| 0.4 | 4.08 |
| 0.3 | 3.1 |
| 0.2 | 1.96 |
| 0.1 | 1.14 |
| 0.03 | 0.36 |

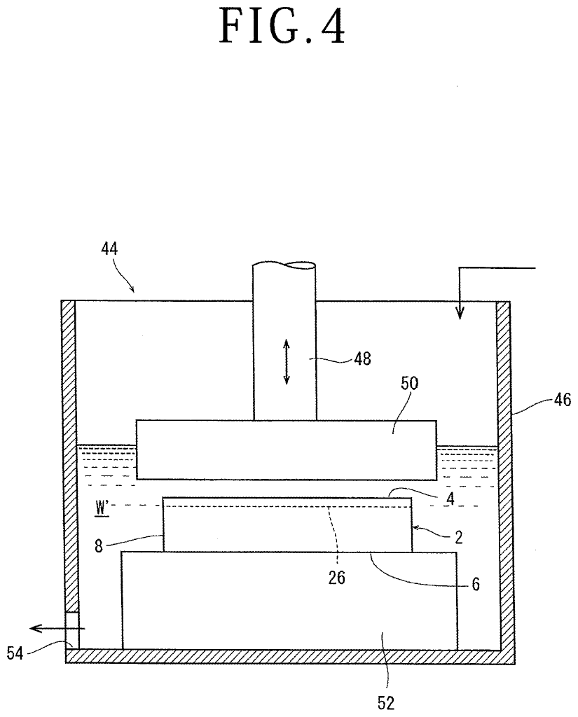

When the degassed water is generated, the degassed water is supplied to the end face of the ingot 2 to form a layer of the degassed water, and an ultrasonic wave is applied to break the peeling start point 26. The breakage of the peeling start point 26 can be carried out, for example, by use of a peeling apparatus 44 depicted in FIG. 4.

The peeling apparatus 44 includes a water tank 46, a rod 48 disposed at an upper part of the water tank 46 in the manner of being liftable and lowerable, and an ultrasonic wave oscillating member 50 mounted to a lower end of the rod 48. A holding table 52 for holding the ingot 2 is provided inside the water tank 46. A discharge port 54 for discharging the degassed water after the wafer is peeled off from the ingot 2 is formed on the lower end side of the water tank 46.

At the time of breaking the peeling start point 26, first, the ingot 2 is held by the holding table 52 with the wafer to be manufactured being directed upward (in other words, with the first surface 4 as an end face nearer to the peeling start point 26 being directed upward). In this instance, an adhesive (for example, an epoxy resin-based adhesive) may be interposed between the second surface 6 of the ingot 2 and an upper surface of the holding table 52 to fix the ingot 2 to the holding table 52, or a suction force may be produced at the upper surface of the holding table 52 to hold the ingot 2 under suction.

Next, degassed water W′ is supplied into the water tank 46 until the water surface becomes above an upper surface of the ingot 2. Subsequently, the rod 48 is lowered, to position the ultrasonic wave oscillating member 50 slightly above the first surface 4 of the ingot 2. The gap between the first surface 4 and the ultrasonic wave oscillating member 50 may be on the order of 2 to 3 mm. Then, an ultrasonic wave is oscillated from the ultrasonic wave oscillating member 50, to break the peeling start point 26 by the ultrasonic wave through the layer of the degassed water W′ present between the first surface 4 and the ultrasonic wave oscillating member 50. As a result, the wafer to be manufactured from the ingot 2 can be peeled off from the peeling start point 26.

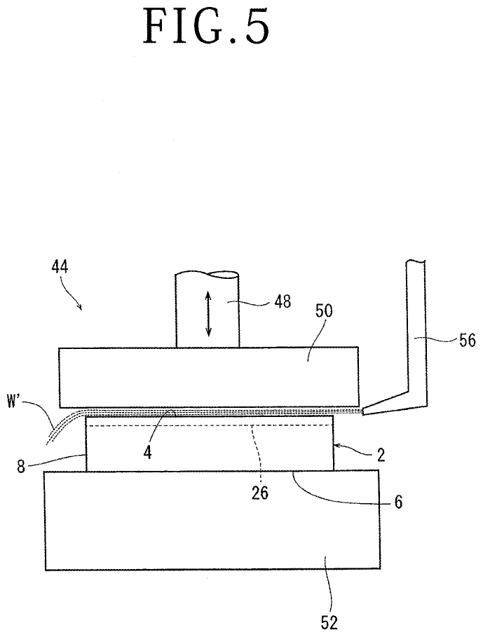

While an example in which the degassed water W′ is reserved in the water tank 46 is described above, a method of supplying, from a supply nozzle 56, the degassed water W′ to the gap present between the first surface 4 of the ingot 2 and the ultrasonic wave oscillating member 50 to thereby form the layer of the degassed water W′, as depicted in FIG. 5, may be adopted.

In this case, the ingot 2 is held by the holding table 52 with the wafer to be manufactured being directed upward, the ultrasonic wave oscillating member 50 is then positioned slightly above the first surface 4, and thereafter, the degassed water W′ is supplied from the supply nozzle 56 to the gap present between the first surface 4 and the ultrasonic wave oscillating member 50 to form the layer of the degassed water W′. Then, an ultrasonic wave is oscillated from the ultrasonic wave oscillating member 50, to break the peeling start point 26 by the ultrasonic wave through the layer of the degassed water W′ present between the first surface 4 and the ultrasonic wave oscillating member 50. As a result, the wafer to be manufactured from the ingot 2 can be peeled off from the peeling start point 26.

In the example depicted in FIG. 4, it takes time to reserve the degassed water W′ in the water tank 46, and it takes time to discharge the used degassed water W′ from the water tank 46 after the peeling of the wafer. In the example depicted in FIG. 5, on the other hand, the layer of the degassed water W′ can be generated instantaneously by supplying the degassed water W′ from the supply nozzle 56 into the gap present between the first surface 4 and the ultrasonic wave oscillating member 50, and the discharge of the used degassed water W′ can be carried out simultaneously with the application of the ultrasonic wave to the ingot 2. Therefore, the example of FIG. 5 can shorten the time for the peeling step as compared with the example of FIG. 4.

As described above, in the present embodiment, the degassed water W′ is supplied to the end face of the ingot 2 to form the layer of the degassed water W′, and the ultrasonic wave is applied to the ingot 2 through the layer of the degassed water W′ to break the peeling start point 26, so that the energy of the ultrasonic wave is not converted into cavitation, and the energy of the ultrasonic wave can effectively be applied to the ingot 2. Hence, the wafer can efficiently be peeled off from the ingot 2.

### Experiment

The present inventors generated a plurality of kinds of degassed water by varying the air pressure inside the decompression tank, applied the ultrasonic wave to the ingot through the layer of the degassed water, thereby breaking the peeling start point to peel off the wafer from the ingot, and measured the time taken from the application of the ultrasonic wave to the ingot to the completion of the peeling of the wafer from the ingot. In addition, sound pressure (amplitude) on the ingot when the ultrasonic wave was applied to the ingot was measured. The frequency of the ultrasonic wave when the degassed water was generated was set to 0.1 MHz, whereas the frequency of the ultrasonic wave applied to the ingot when the peeling start point was broken was set to 25 kHz. The temperature of the degassed water was 20° C.

### Experimental Results

| Oxygen content of | | |
|---|---|---|
| degassed water | Peeling time | Sound pressure |
| (mg/liter) | (second) | (V) |
| 8.1 | 1,352 | 1.54 |
| 6.55 | 1,223 | 1.56 |
| 5.8 | 1,123 | 1.66 |
| 5.48 | 1,082 | 1.68 |
| 4.97 | 1,002 | 1.88 |
| 4.08 | 815 | 1.88 |
| 3.1 | 753 | 1.88 |
| 1.96 | 356 | 2.20 |
| 1.14 | 243 | 2.32 |
| 0.36 | 236 | 3.12 |

As understood with reference to the above-described experimental results, as the oxygen content of the degassed water was lower, the time taken until the wafer was peeled off from the ingot was shortened, and the sound pressure on the ingot was increased. In addition, the peeling time was 753 seconds when the oxygen content of the degassed water was 3.1 mg/liter, whereas the peeling time was 356 seconds when the oxygen content of the degassed water was 1.96 mg/liter. That is, when the oxygen content of the degassed water was changed from 3.1 mg/liter to 1.96 mg/liter, the peeling time was reduced to below one half. Accordingly, from the viewpoint of efficient manufacture of the wafer from the ingot, it is preferable to generate the degassed water having an oxygen content of not more than 2.0 mg/liter.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer manufacturing method for manufacturing a wafer from an ingot, comprising:
a peeling start point forming step of applying, to the ingot, a laser beam of such a wavelength as to be transmitted through the ingot, with a focal point of the laser beam positioned at a depth corresponding to a thickness of the wafer to be manufactured, from an end face of the ingot, to form a modified layer, thereby forming a peeling start point; and
a peeling step of peeling off, from the peeling start point, the wafer to be manufactured from the ingot,
wherein, in the peeling step, degassed water is supplied to the end face of the ingot to generate a degassed water layer, and an ultrasonic wave is applied to break the peeling start point.

2. The wafer manufacturing method according to claim 1, wherein, in the peeling step, the ultrasonic wave is applied to water reserved in a decompression tank, to decompress an inside of the decompression tank, thereby generating the degassed water.

3. The wafer manufacturing method according to claim 1, wherein, in the peeling step, degassed water having an oxygen content of not more than 2.0 mg/liter is generated.

4. The wafer manufacturing method according to claim 1, wherein the ingot is a silicon carbide ingot.

5. The wafer manufacturing method according to claim 4,
wherein the silicon carbide ingot has a first surface, a second surface on a side opposite to the first surface, a c-axis extending from the first surface to the second surface, and a c-plane orthogonal to the c-axis, the c-axis being inclined relative to a perpendicular to the first surface, an off-angle being formed by the c-plane and the first surface, and
the peeling start point forming step includes
a modified layer forming step of relatively moving the focal point of the laser beam and the silicon carbide ingot in a direction orthogonal to a direction in which the off-angle is formed, to form a rectilinear modified layer, and
an indexing step of relatively moving the focal point of the laser beam and the silicon carbide ingot in the direction in which the off-angle is formed, to thereby perform index feeding by a predetermined amount.
